(19) United States
(12) Patent Application Publication
(10) Pub. No.: US 2007/0205775 A1
(43) Pub. Date: Sep. 6, 2007

(54) Device , Sensor Arrangement and Method for the Capacitive Position Finding of a Target Object

(76) Inventors: Hardi Voelkel, Viernheim (DE); Ulrich Ehrenfried, Mannheim (DE)

Correspondence Address: HOFFMAN WARNICK & D'ALESSANDRO, LLC, 75 STATE STREET, 14TH FLOOR, ALBANY, NY, 12207, US

(21) Appl. No.: 10/599,879

(22) PCT Filed: Mar. 31, 2005
(86) PCT No.: PCT/EP05/03389

§ 371 Date: Oct. 12, 2006

(30) Foreign Application Priority Data
Apr. 16, 2004 (DE) 10 2004 018 630.8

(51) Int. Cl. G01R 27/26

(52) U.S. Cl. 324/662

(57) ABSTRACT

The present invention relates to a device for capacitive position finding of an object, with a plurality of capacitive probes distributed over an area in which a position of the object is to be established. According to the invention the device is characterized in that the probes are in each case connected by means of coupling capacitances to a voltage source and can be supplied with a supply voltage and that an evaluating device connected to the probes is provided permitting the processing of the probe signals to an output signal, which is a measure for the position of the object to be established. In further aspects the invention relates to a probe/sensor arrangement and a method for capacitive position finding of an object.

The invention relates to a device for the capacitive position finding of a target object according to the preamble of claim 1.

In further aspects the invention relates to a sensor arrangement for capacitive position finding of a target object according to the preamble of claim 12 and a method for capacitive position finding of a target object according to the preamble of claim 17.

Such a device has a plurality of capacitive probes, which are distributed over a detection area in which a position of the target object is to be found.

Such a sensor arrangement for capacitive position finding of a target object has a plurality of capacitive probes, which are distributed in a first area and in particular on one side, of a support over a detection area in which a position of the target object is to be found.

In such a method for capacitive position finding of a target object a plurality of capacitive probes are arranged over a detection area in which a position of the target object is to be found.

In the device, sensor arrangement and method in each case the capacitances or capacitance changes of the probes relative to the environment as a function of the position or position change of the target object or quantities derived therefrom serve as measured quantities.

The term target object is to be interpreted as widely as possible. It can be constituted by discreet objects and also materials, i.e. particularly fluids, such as liquids and gases, as well as bulk materials. Hereinafter the terms target object and object are used as synonyms. The term position with respect to fluids and bulk materials is also understood to mean their distribution or extension.

Such a device is described in DE 198 51 213 C1. In the said disclosed, capacitive sensor arrangement a plurality of capacitor plates is applied to a flexible foil. The foil is bent to a desired shape, e.g. a U or S-shape and used for the detection of fluids, i.e. liquid or gaseous media. The measured quantity is the capacitance modified by the dielectric characteristics of the medium to be detected brought into the vicinity of the given probe.

A capacitive proximity switch is disclosed in DE 196 23 969 A1.

DE 195 03 203 A1 describes a capacitive sensor, in which a position of an object or a mass or weight distribution can be determined by measuring a displacement current.

An array or matrix of capacitive position sensors is disclosed in EP 609 021 A2. The object of U.S. Pat. No. 5,136,286 is a device for the capacitive determination of the orientation of a measuring instrument pointer, where specially shaped electrodes are used. A device for the capacitive monitoring of the composition of a sample, e.g. of blister packs for medicaments, is described in EP 302 727 A2.

Inductive methods and devices are also known in connection with the position finding of a target object. Such devices are used in connection with automation in numerous industrial processes. There are also numerous possible uses in car technology. For example, DE 102 04 453 A1 describes an analog, inductive displacement pickup enabling the determination of a relative displacement between a vehicle seat and a vehicle body. The measuring principle is the change to the magnetic induction brought about in the case of a relative displacement of a test body made from a high magnetic permeability material.

In this connection linear displacement or path measuring systems are known, in which a tilted longitudinal coil, an inductive displacement pickup with magnetic coupling or an inductive displacement pickup comprising numerous individual coils is used. It has been shown to be unfavourable in these solutions that the detection signals have a comparatively large spacing dependence and consequently only limited distances can be monitored. Moreover, frequently for fundamental reasons only ferromagnetic objects can be detected. This is undesirable due to the mechanical sensitivity of ferromagnetic objects. Finally, solutions with a large number of individual coils admittedly permit the monitoring of a very large area but, since a crosstalk of the signals of the individual coils is to be avoided, each individual coil is supplied with a different frequency, such solutions involve high circuitry and equipment costs.

The object of the invention is to provide a device, a sensor or probe arrangement and a method for the capacitive position finding of a target object enabling the latter to be found over a long distance with high precision. The device and probe arrangement should also be easy to implement from the design standpoint.

In a first aspect of the invention the object is achieved by the device having the features of claim 1.

In further aspects of the invention the object is achieved by the probe arrangement having the features of claim 11 and by the method having the features of claim 16.

Advantageous further developments of the device and sensor arrangement according to the invention, as well as preferred variants of the inventive method form the object of subclaims.

The device according to the preamble is inventively characterized in that the probes are in each case connected via coupling capacitances to a voltage source and can be supplied with a supply voltage and that an evaluating device connected to the probes is provided and enables the probe signals to be processed to an output signal, which is a measure for the position of the target object to be found.

The sensor arrangement of the above-described type is inventively further developed in that for the formation of coupling capacitances by means of which a supply voltage can be coupled onto the probes, in a second area, particularly on an opposite side, or within the support, is provided at least one coupling electrode and that the support is formed at least partly from a dielectric material for the formation of a coupling layer.

For the further development of the method according to the preamble for capacitive position finding of a target object, the invention proposes that the probes are in each case supplied via coupling capacitances with a supply voltage and that the probe signals are processed with the aid of an evaluating device to an output signal, which is a measure for the position of the target object to be detected.

According to a first fundamental idea of the present invention a supply voltage, e.g. an a.c. voltage, is coupled by means of coupling capacitances onto the plurality of capacitive probes.

A second fundamental idea of the present invention in connection with the probe arrangement is to construct it in a very compact manner on a support, in which a plurality of probes is positioned in a first area and in which, spaced from the first area, in a second area is provided at least one coupling electrode for forming the coupling capacitances with the probes.

The probes and coupling electrodes can be located both directly on the outside of the support, which is at least partly formed from a dielectric material, or in the interior thereof.

A first essential advantage of the invention is that the position of a random metallic or nonmetallic object can be detected, because in each case there is a change to the capacitance of the probes relative to the environment. The arrangement of the probes, e.g. along a path, can in principle be randomly long and can assume random shapes. It is e.g. possible to have a straight, i.e. a linear path, circular path or zigzag path, whilst it is also possible to have probe configurations which are flat, i.e. two-dimensional, or spatial, i.e. three-dimensional.

Thus, random topologies are possible for the probes, particularly concentric, rectangular and matrix/array-like arrangements. In principle all “uneven” technically manufacturable topologies are possible.

Apart from objects to be detected in discreet manner, it is possible with the device and method according to the invention to detect fluids, i.e. liquids and gases, as well as bulk materials, independently of the given material. In particular, it is also possible to detect robust, metallic targets, which is important for numerous applications.

A further important advantage of the presently proposed, contactless operating position finding system is that the device, probe arrangement and method can in each case be implemented with limited construction and design costs. According to the invention, the evaluating device always uses the probe signals, e.g. the probe voltages, for determining the position of the target object to be detected.

It is also advantageous with respect to the attainable detection precision that error magnitudes simultaneously acting on all probes, i.e. all channels, during evaluation no longer exert any influence. These error magnitudes include temperature effects and electrical interference, e.g. as a result of electric fields during welding or radio interference voltages, as well as effects arising from the dependence of the probe signals on the given object spacings.

The material of the target object to be detected acts in the same way on the capacitances of all the probes, so that the result of the evaluation is independent of the material of the target object to be detected.

The target object or object can be made from metal, plastic, glass, ceramic, paper and wood, i.e. from in principle a random material. If the object to be detected is made from a conductive material, detection can also take place independently of whether or not the object is earthed or grounded.

The invention has particularly important practical applications for all linear path measurements, for path or angular measurements in dynamometers as well as for fill level measurements for liquids and bulk materials, either directly or through a container wall.

According to another fundamental idea of the present invention the coupling capacitances and the capacitances of the probes with respect to the environment and which vary due to the variable position of the target object to be detected, in each case form capacitive voltage dividers.

Thus, according to the invention and unlike in the prior art, there is not a direct supply to the capacitive probes, which can also be referred to as measuring probes and instead a voltage divider is built up via the coupling capacitance or capacitances and the measuring capacitance or capacitances.

Unlike in the prior art, where the term coupling capacitances is also understood to mean a capacitance, whose coupling is varied by approach to an object, the term “coupling capacitance” here is understood to mean a “coupling in” capacitance. Thus, it is the capacitance by means of which the a.c. voltage is coupled onto the measuring probe.

An important structural and fundamental difference of the present invention compared with the prior art is that the capacitance directly supplied by the generator, i.e. the coupling capacitance, always remains substantially uninfluenced. Therefore, the inventive probe arrangement can be implemented with discreet capacitors. Unlike in the prior art, in the present invention initially the follow-up capacitance is modified by the approach of an object. Such a follow-up capacitance is not present in the prior art.

In a particularly preferred variant of the inventive method the probe voltages are evaluated as probe signals.

Thus, as will be explained hereinafter, apart from the supply voltage it is essentially the ratio of the probe capacitance to the coupling capacitance which passes into the measured signal.

In a preferred development of the inventive device is provided at least one inventive probe arrangement. In the probe arrangement according to the invention not only can the probes and coupling capacitances be made particularly compact and simple, but they also allow a very high variability of the probe arrangement.

For example, the support can be constructed as a printed circuit board, so that from the production standpoint use can be made of highly developed circuit board technology.

The probes can fundamentally have a random shape and size and preferably plate-like electrodes, e.g. on a circuit board are used. As a function of the desired local/position resolution and sensitivity of the probes, the surface area thereof can range from a few square millimetres to a few square centimetres and beyond. It is particularly appropriate to select in planned manner the shape and size of the probes with regards to the target object to be detected.

A particularly high variability with respect to the area to be monitored can be achieved if the support is constructed as a flexible printed circuit board. Such a flexible circuit board can in principle be brought into any desired shape, so that random three-dimensional areas can be monitored. It is e.g. possible to monitor the position of a lever moving on a circular or spherical segment.

The support can also be constituted by a foil, in which the corresponding metallic structures are applied using a suitable mask, e.g. using an evaporation coating procedure.

The probe arrangement can be in the form of a bilaterally metallized, continuous dielectric in one piece or in the form of a bilaterally metallized, interrupted dielectric with distributed capacitances.

However, a certain design freedom with respect to the three-dimensional areas to be monitored can also be obtained in that several inventive probe arrangements are used, where the support is constituted by a conventional printed circuit board. Separate circuit boards can also be advantageous for compensating any mechanical stresses or temperature fluctuations.

There is also a considerable design freedom regarding the coupling electrodes. In principle, the coupling electrode can be subdivided into a plurality of individual electrodes. This can be appropriate if the individual coupling capacitances are to be supplied with different potentials. In a very simple design variant the coupling electrode is constructed as a continuous potential surface. This is particularly important, because in the case of the capacitive position finding system proposed here, unlike in an inductive detection system with a plurality of coils, the individual capacitances do not have to be supplied with different frequencies. Thus, the continuous coupling electrode serves as a common base or foot, which can be supplied with a supply voltage, particularly an a.c. voltage. Thus, compared with an inductive system, the electronics required can be made much simpler.

The probe arrangement according to the invention can be used with particular usefulness if the support carries additional parts of evaluation electronics, i.e. parts of the evaluating device. This makes it possible to obtain very compact structures.

The probes and coupling electrodes can in principle be placed within the support. In a simple variant, which is e.g. made from a bilaterally coated circuit board, the probes and coupling electrodes are in fact placed directly on the outside of the support. An arrangement of coupling electrodes within the support can be preferable if for shielding or receiving further circuit components on or in said support, further metal coatings are provided. These variants are appropriately used where shielding against interference fields is necessary. In principle, it is also possible for the coupling capacitances to be at least partly constructed as discreet capacitors. This can e.g. be advantageous if individual probes have to be differently positioned for different applications.

The precision of the evaluation and therefore position detection can be increased if at least one of the probes is constructed and/or used as a reference probe. This can in particular be an inactive measuring probe, i.e. a probe positioned in such a way that the target object to be detected never enters the detection area thereof. In principle, the signal of an active measuring probe can also be used as a reference if it is ensured that the object to be detected at the time in question is not in the detection area of said probe. With the aid of the reference measurement at the reference probe it is then e.g. possible to adjust the voltage amplitudes of the remaining amplitudes.

It is particularly advantageous in this connection if the measuring electrodes or measuring probes have the same or at least a similar shape and/or surface area to the reference electrode or electrodes. The evaluation of the relevant signals with respect to position determination is then particularly simple.

In a simple development the evaluating device has a rectifier for at least each probe.

In order to mathematically process the probe signals, the evaluating unit appropriately has a central processing unit. It can in principle also be a circuit built up from analog components, e.g. an operational amplifying circuit, but preferably a microprocessor is used. In this variant there is then also at least one analog-digital converter for digitizing the analog measuring signals.

In cost-advantageous variants there is no need for a large number of analog-digital converters and instead one or more multiplexers can be provided in the evaluating device and via them can be supplied to the central processing unit, e.g. the microprocessor the probe signals of at least two probes.

If for certain applications the independence with respect to a scanning frequency of a multiplexer is desired, it is obviously also possible to equip each channel with rectifiers, possible processing electronics and analog-digital converters.

With regards to the mathematical evaluation of the probe signals, e.g. the probe voltages, a high degree of freedom exists. According to the principle of known bridge circuits, it is e.g. possible to evaluate the differences of the individual signal voltages. In a preferred variant of the inventive method the quotients of several voltage amplitudes are formed for evaluation purposes. This also makes it possible to eliminate undesired interference effects acting in the same way on all probes, such as the temperature and electrical interference fields.

Combinations of these methods are also possible.

The speed of signal processing can be increased if the evaluating device has a signal processor for the preprocessing of the analog probe signals.

Further advantages and features of the inventive device, probe arrangement and method are described in greater detail hereinafter relative to the attached diagrammatic drawings, wherein show:

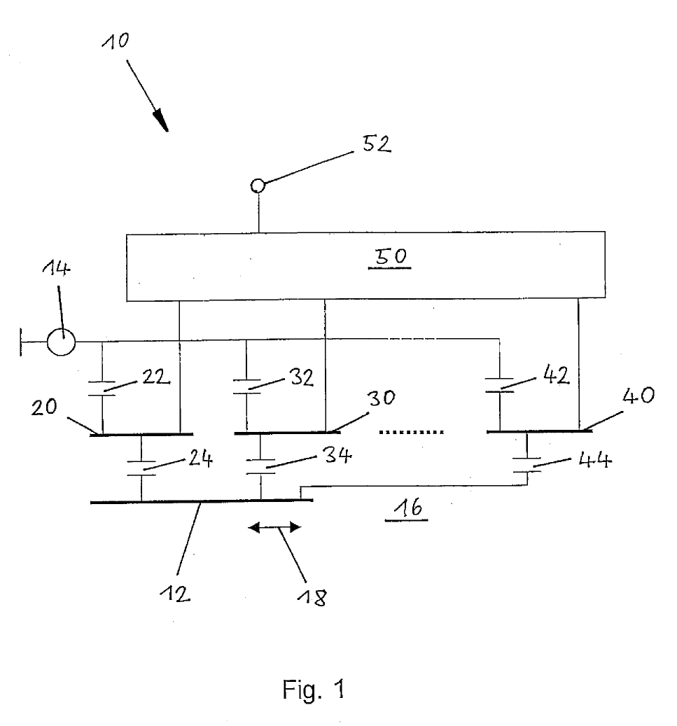

FIG. 1 A diagrammatic representation of a first embodiment of an inventive device.

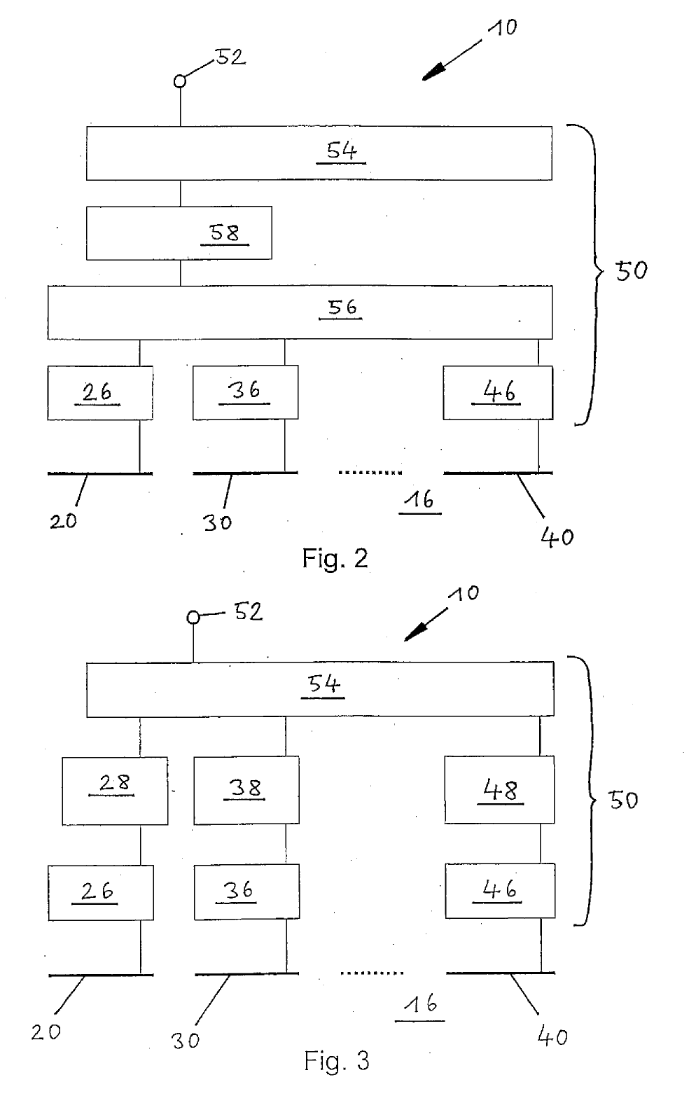

FIG. 2 A diagrammatic partial view of a second embodiment of an inventive device.

FIG. 3 A diagrammatic partial view of a third embodiment of the inventive device.

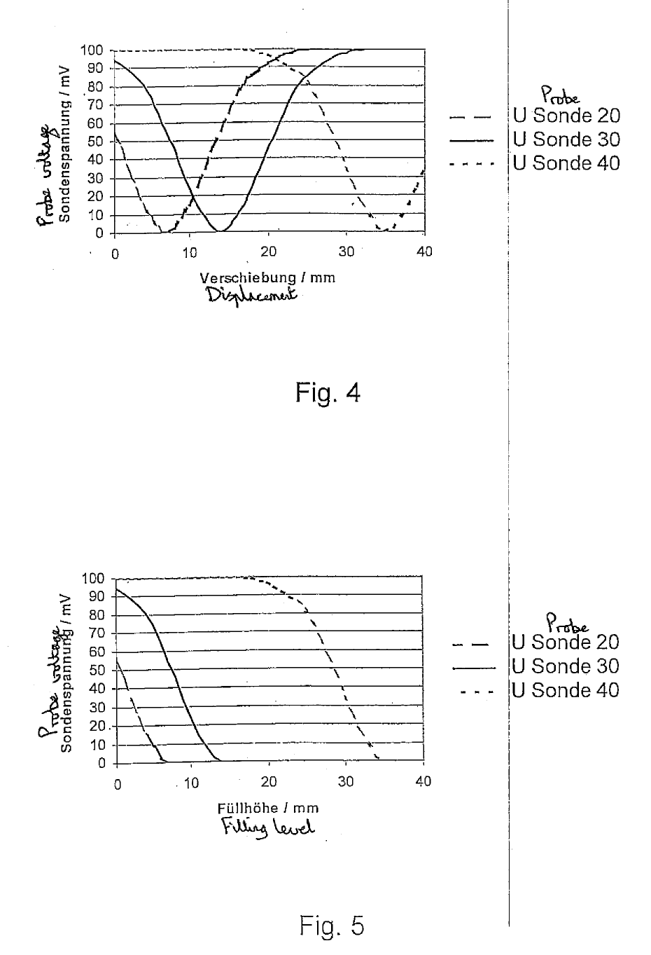

FIG. 4 A graph in which the probe voltage of three probes is plotted against the position of an object to be detected.

FIG. 5 A graph in which the signal voltage of three probes is plotted as a function of the filling level of a bulk material or a liquid to be detected.

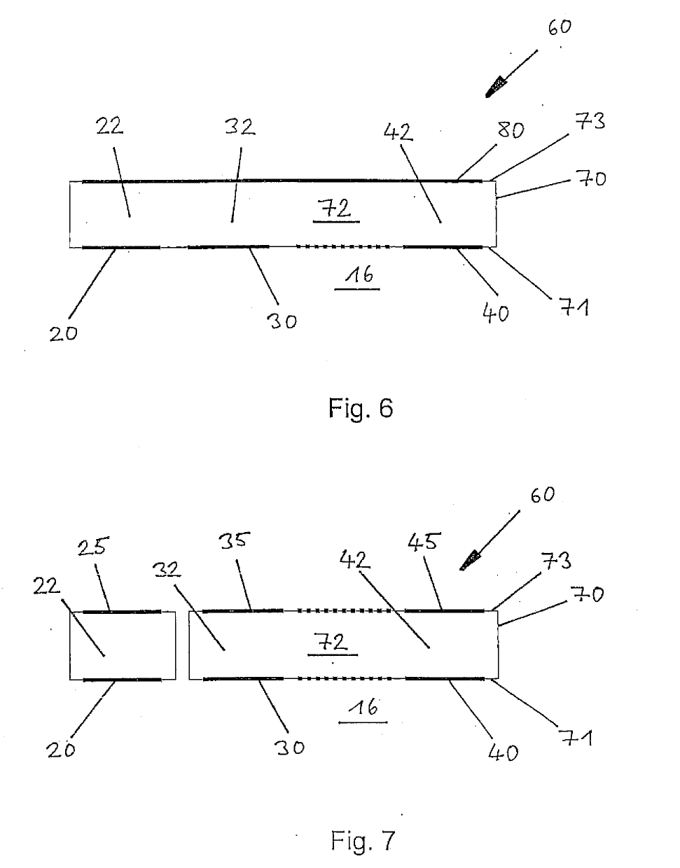

FIG. 6 A first embodiment of an inventive probe arrangement.

FIG. 7 A second embodiment of an inventive probe arrangement.

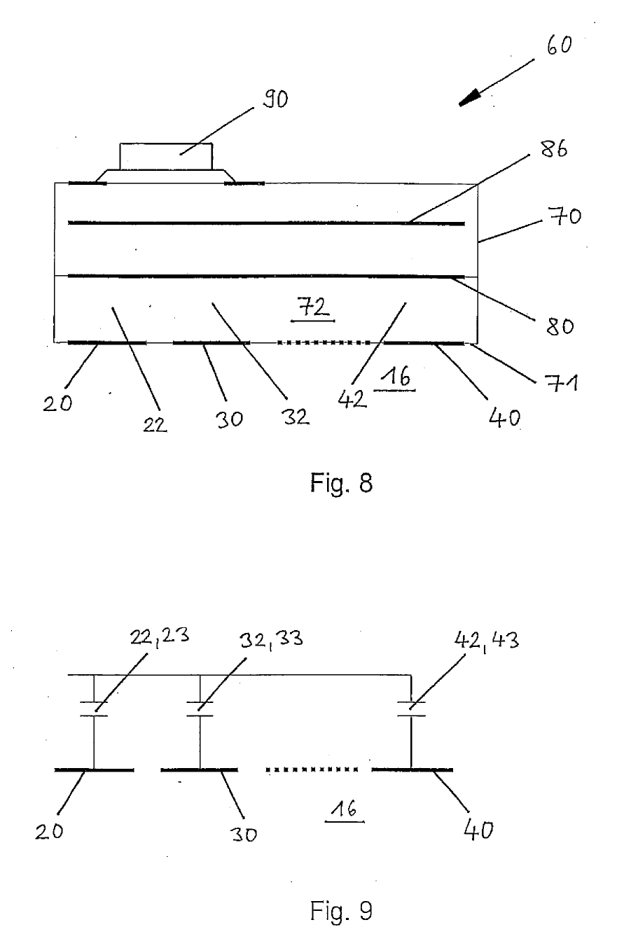

FIG. 8 A third embodiment of an inventive probe arrangement.

FIG. 9 An alternative example regarding the structure of the coupling capacitances.

FIG. 1 diagrammatically shows a first embodiment of a device 10 according to the invention. Device 10 generally comprises a plurality, i.e. at least two, capacitive measuring plates or probes 20, 30, 40. By means of coupling capacitors 22, 32, 42 an a.c. voltage as the supply voltage is coupled from a voltage source 14 onto probes 20, 30, 40. Capacitances 24, 34, 44 are formed between the individual probes 20, 30, 40 and the object 12 to be detected as the target object. These capacitances are shown in FIG. 1 in the manner of an equivalent circuit diagram. The coupling capacitances 22, 32, 42 must not necessarily be discreet capacitors.

The probes 20, 30, 40 are also connected in each case to an evaluating device 50, to be described hereinafter relative to FIGS. 2 and 3. Evaluating device 50 evaluates the probe voltages of probes 20, 30, 40 and generates an output signal 52 as a function of the position of object 12 relative to probes 20, 30, 40.

For simplification purposes an earthed or grounded object 12 is assumed for illustrating the operation of the inventive device 10. The reference potential of the voltage source 14 is also earth or ground. Coupling capacitance 22 and capacitance 24 form a capacitive voltage divider with the probe voltage as the mean voltage. The probe voltage U20 arises from the coupled in voltage U0, the value C22 of coupling capacitance 22 and the value C24 of capacitance 24:
U20=U0*1/(1+C24/C22),
and correspondingly for the further probes 30, 40.

The nearer the object 12 is to a probe 20, 30, 40, the lower the probe voltage. Therefore the probe voltages of the different probes 20, 30, 40 are dependent on the position of object 12, the probe indicating the lowest level being that which is closest to the object 12. As coupling capacitances 22, 32, 42 are supplied with an a.c. voltage from voltage source 14, there is also in each case an a.c. voltage at probes 20, 30, 40 and this is processed with the aid of evaluating device 50.

Object 12 has been looked upon as earthed merely for simplification purposes. The measurement functions just as well with unearthed or ungrounded target objects. Compared with earth potential each object 12 to be detected has a parasitic capacitance. The capacitance of one of the probes 20, 30, 40 to earth is formed to the earth potential through the series connection of the capacitance of the probe to object 12 and the parasitic capacitance of object 12. The capacitance of the probe against an earthed object is higher than the capacitance of the probe to an unearthed object due to this series connection. Therefore an unearthed object 12 modifies the probe voltages to a lesser extent than an earthed object 12.

Arrow 18 in FIG. 1 indicates a shift of object 12 within the detection area 16.

Evaluating circuit 50 always uses several probe voltages for determining the position of object 12. Error magnitudes, such as e.g. temperature, electrical interference due to welding fields or areas or radio interference voltages, together with the spacing of object 12 with respect to probes 20, 30, 40, which act simultaneously on all channels, can in this way be calculated out.

As the material of object 12 acts identically on all capacitances 24, 34, 44, the result of the evaluation is also independent of the material of object 12. As the parasitic capacitance of an unearthed object 12 is equal for all probes 20, 30, 40, the evaluation result is also independent of the earthing of the object.

Two examples for the design of evaluating device 50 are illustrated in detail in FIGS. 2 and 3. Equivalent components are in each case given the same reference numerals.

In the case of the example shown in FIG. 2, the voltage of probes 20, 30, 40 is in each case initially passed to a rectifier 26, 36, 46. The rectified signals are then supplied across a multiplexer 56 and an analog-digital converter 58 to a microprocessor 54. From the digitized signals the microprocessor 54 calculates an output signal as a function of the position of object 12 and outputs this signal at output 52. In this example there is no need for the numerous expensive analog-digital converters.

Unlike in the example of FIG. 2, in the case of the variant in FIG. 3 each probe channel has its own analog-digital converter 28, 38, 48. The evaluation of the voltages of probes 20, 30, 40 can therefore in principle take place independently of a scanning frequency of a multiplexer.

It is obviously also possible to have mixed forms of the examples shown in FIGS. 2 and 3.

The coupling capacitances 22, 32, 42 of device 10 shown in FIG. 1 can in principle be constructed as discreet capacitors 23, 33, 43, as is diagrammatically illustrated in FIG. 9. This variant is particularly appropriate if the positioning of one or more probes is to be modified, e.g. in order to monitor different areas or paths. In the example shown in FIG. 9 probes 20, 30, 40 are positioned linearly in an area 16 to be monitored.

However, for the positioning of probes 20, 30, 40, it is particularly advantageous to have an inventive probe arrangement 60, whereof embodiments are shown in FIGS. 6 to 8.

The first example of an inventive probe arrangement 60 shown in FIG. 6 is made from a bilaterally coated printed circuit board. On a first side 71 of the circuit board functioning as a support 70 the probes 20, 30, 40 are formed from the circuit board coating. The individual probes 20, 30, 40 can in principle have random shapes and in particular also different sizes. On the opposite outside 73 of support 70 is formed a continuous coupling electrode 80 for forming the coupling capacitances 22, 32, 42. This coupling electrode 80, which in principle assumes the function of a capacitor plate and is used for the connection of the a.c. voltage generator, is also referred to as a foot or base point.

As only very low currents flow across the capacitive voltage dividers, the connection to the supply voltage can be of a relatively high ohmic nature, e.g. here ohmic resistances of up to 1 megaohm are possible. Therefore the circuit structure is very uncritical.

According to the invention a coupling layer 72 is also formed by the material of circuit board 70 between coupling electrode 80 and probes 20, 30, 40 and as a result of the dielectric characteristics of the circuit board material it increases the coupling capacitances 22, 32, 42. In principle, the coupling layer 72 can be formed from a material with a determinable dielectric, e.g. a circuit board material, plastic, glass, ceramic, air or foam.

The example shown in FIG. 7 differs from the variant of FIG. 6 essentially in that only probes 30, 40 are placed on a common support 70, whereas probe 20 is placed on a separate support. The variant of FIG. 7 also has no continuous coupling electrode and instead there are in each case separate coupling electrodes 25, 35, 45 for forming the coupling capacitances 22, 32, 42. As a result of the separate base points, each coupling capacitance 22, 32, 42 can in principle be supplied with a different a.c. voltage. For the most frequent application in which the coupling electrodes 25, 35, 45 form a unitary potential surface, once again the connections between coupling electrodes 25, 35, 45 can be of a relatively high ohmic nature.

A more complex embodiment is shown in FIG. 8, where once again the probes 20, 30, 40 are admittedly again placed on the outside 71 of support 70. However, coupling electrode 80 is placed in the interior of support 70, which can e.g. be a multi-layer printed circuit board. Above the coupling electrode 80 is provided a further metallic layer 86, which can optionally be used for shielding the probes against the irradiation of interference fields. On the side of support 70 opposite to probes 20, 30, 40 is diagrammatically illustrated by component 90 an electric circuit. Here again probes 20, 30, 40 and coupling electrode 80 in each case form coupling capacitances 22, 32, 42, which are increased by the dielectric properties of coupling layer 42. With the probe arrangement shown in FIG. 8 it is possible to obtain very compact structures, because simultaneously parts of evaluation electronics can be integrated.

In order to be able to uninterruptedly establish the movement of an object 12, probes 20, 30, 40 must be positioned relative to one another in such a way that their sensitivity curves at least partly overlap.

An example for a simple, contactless determination of the shift of an object 12 when using a device and method according to the invention is illustrated by referring to FIG. 4.

FIG. 4 plots the probe voltage of three probes 20, 30, 40, which are arranged as diagrammatically shown in FIGS. 1 to 3. As can be gathered from FIG. 4, the minimum value of the voltage of probe 20 is reached when probe 20 and object 12 precisely face one another. If object 12 moves in the direction of probe 30, the voltage at probe 20 becomes higher again and the voltage at probe 30 correspondingly lower.

Through the local recording of the probe voltages over time, it is possible to represent as a function of time the position of object 12.

FIG. 4 also shows that the sensitivity curves of probes 20, 30 greatly overlap, so that a high position resolution is achieved in this area.

A further use example of the present invention is illustrated in FIG. 5, where once again the voltages of three probes 20, 30, 40 are represented for an application in which the fill level of a liquid or a bulk material as the target object is to be detected.

In the detection of liquids or bulk materials probes 20, 30, 40 are preferably positioned vertically. If the liquid or bulk material level rises the capacitances of the probes located further upwards is successively raised with respect to the environment. The capacitance values of the probes lower down remain unchanged due to the liquid or bulk material still present there. Thus, the evaluation of the probe voltages must be performed differently in the case of liquids or bulk materials as compared with an individual object to be detected.

These contexts are illustrated in FIG. 5.

The minimum value of the voltage of probe 20 is reached when said probe 20 is completely covered by liquid or bulk material. In the case of a further liquid or bulk material level rise, the voltage at probe 30 decreases and finally drops to the minimum value. Unlike in the case illustrated in FIG. 4, the probe voltages obviously do not rise further as soon as the corresponding probe has been covered with liquid or bulk material.

The present invention provides a novel device, sensor arrangement and method for contactless, capacitive position finding of an object, which on the one hand permits a particularly precise determination of the position of an object, or also liquids and bulk materials, and on the other can be implemented in a particularly simple manner from the construction and design standpoint, particularly when compared with known inductive solutions.

1. Device for the capacitive position finding of a target object, particularly for performing the method according to one of the claims 14 to 18,
having a plurality of capacitive probes (20, 30, 40) distributed over a detection area (16) in which a position of the target object (12) is to be determined,
characterized in that
a dependence of the probe voltages on the spacing of the target object (12) from the given capacitive probe (20, 30, 40) is evaluatable for position determination,
that the probes (20, 30, 40) are in each case connected across coupling capacitances (22, 32, 42) to a voltage supply (14) and can be supplied with a supply voltage, the capacitances (24, 34, 44) of probes (20, 30, 40) to the environment together with the coupling capacitances (22, 32, 42) in each case forming a capacitive voltage divider with the probe voltages as mean voltages and
that an evaluating device (50) connected to the probes (20, 30, 40) is provided and which enables the probe voltages to be processed to an output signal (52), which is a measure for the position of the target object (12) to be found.

2. Device according to claim 1,
characterized in that
the coupling capacitances (22, 32, 42) are at least partly constructed as discreet capacitors (23, 33, 43).

3. Device according to claims 1 or 2,
characterized in that
at least one of the probes (20, 30, 40) is constructed as a reference probe.

4. Device according to one of the claims 1 to 3,
characterized in that
the probes (20, 30, 40) are distributed over a three-dimensional detection area (16).

5. Device according to one of the claims 1 to 4,
characterized in that
the evaluating device (50) for each probe (20, 30, 40) has a rectifier (26, 36, 46).

6. Device according to one of the claims 1 to 5,
characterized in that
the evaluating device (50) has a central processing unit, particularly a microprocessor (54).

7. Device according to claim 6,
characterized in that
the evaluating unit (50) has a multiplexer (56) by means of which the probe signals of at least two probes (20, 30, 40) can be supplied to the central processing unit.

8. Device according to one of the claims 1 to 7,
characterized in that
the evaluating device (50) has a signal processor for preprocessing the analog probe signals.

9. Device according to one of the claims 1 to 8,
characterized in that
the plurality of capacitive probes (20, 30, 40) which, in a first area, particularly on one side (71), of a support (70) are distributed over the detection area (16) in which the position of the target object (12) is to be found, that for forming the coupling capacitances (22, 32, 42) in a second area, particularly on a facing side (73), of the support (70) there is at least one coupling electrode (80) by means of which a supply voltage can be coupled onto the probes (20, 30, 40) and
that the support (70) for forming a coupling layer (72) is at least partly made from a dielectric material.

10. Device according to claim 9,
characterized in that
the support (70) is constructed as a more particularly flexible printed circuit board.

11. Device according to one of the claims 9 or 10,
characterized in that
at least parts (90) of evaluating electronics are placed on the support (70).

12. Device according to one of the claims 9 to 11,
characterized in that
the coupling electrode (80) is constructed as a unitary potential surface, particularly as a continuous, metallic layer.

13. Device according to one of the claims 9 to 12,
characterized in that
further metal layers (86) are provided for shielding or receiving circuit components on or in support (70).

14. Method for capacitive position finding of a target object, in which a plurality of capacitive probes (20, 30, 40) is arranged over a detection area (16) in which a position of the target object (12) is to be determined,
characterized in that
the probe voltages are dependent on the spacing of the target object from the given probe and are evaluated for determining the position of the target object,
that the probes (20, 30, 40) are in each case supplied with a supply voltage across coupling capacitances (22, 32 42), capacitive voltage dividers with the probe voltages as mean voltages being formed through the coupling capacitances (22, 32, 42) and by the capacitances (24, 34, 44) of probes (20, 30, 40) to the environment varying as a result of a position change of the target object (12) to be detected and
that the probe voltages are processed with an evaluating device (50) to an output signal, which is a measure of the position of the target object (12) to be found.

15. Method according to claim 14,
characterized in that
a discreet object, a liquid or a bulk material is detected.

16. Method according to claim 14 or 15,
characterized in that
all the coupling capacitances (22, 32, 42) are supplied with the same supply voltage with a given frequency.

17. Method according to one of the claims 14 to 16,
characterized in that
the quotients of several probe voltages are formed for evaluating the probe signals.

18. Method according to one of the claims 14 to 17,
characterized in that
the signal voltage of at least one reference probe is taken into account during evaluation.
